(19) United States
(12) Patent Application Publication
(10) Pub. No.: US 2007/0096154 A1
(43) Pub. Date: May 3, 2007

(54) Standard cell

(76) Inventors: Hiroyuki Shimbo, Osaka (JP); Junichi Yano, Osaka (JP)

Correspondence Address: MCDERMOTT WILL & EMERY LLP, 600 13TH STREET, N.W., WASHINGTON, DC, 20005-3096, US

(21) Appl. No.: 11/541,657

(22) Filed: Oct. 3, 2006

(30) Foreign Application Priority Data
Oct. 3, 2005 (JP) 2005-290397

(51) Int. Cl. H01L 27/10; H01L 29/73

(52) U.S. Cl. 257/207

(57) ABSTRACT

In a standard cell in which a substrate voltage control technique is implemented, a plurality of normal power supply wires are disposed at previously set positions. Therefore, when the standard cell is disposed adjacent to another standard cell having such normal power supply wires, these normal power supply wires are connected to each other. In addition, the standard cell is provided with a substrate power supply terminal which is not connected to that of the other standard cell when the other standard cell is disposed adjacent to the standard cell. Therefore, when a semiconductor integrated circuit is composed of a plurality of the standard cells, a wiring route of an inter-cell substrate power supply wire, or the like can be freely set.

### CROSS REFERENCE TO RELATED APPLICATIONS

This Non-provisional application claims priority under 35 U.S.C.§119(a) on Patent Application No. 2005-290397 filed in Japan on Oct. 3, 2005, the entire contents of which are hereby incorporated by reference.

### BACKGROUND OF THE INVENTION

1. Field of the Invention

The present invention relates to a standard cell, which is an elementary unit for use in designing layouts of semiconductor integrated circuits, a semiconductor integrated circuit including the standard cells, a method for designing the semiconductor integrated circuit, an apparatus for designing the semiconductor integrated circuit, and a standard cell library. More particularly, the present invention relates to a standard cell which has a substrate control function of controlling a substrate voltage and source voltages of transistors separately, a semiconductor integrated circuit including the standard cells, a method for designing the semiconductor integrated circuit, an apparatus for designing the semiconductor integrated circuit, and a standard cell library.

2. Description of the Related Art

Conventionally, there are semiconductor integrated circuits in which standard cells are disposed and interconnected to achieve a desired function. Of the semiconductor integrated circuits, there is a semiconductor integrated circuit which has a substrate voltage control function so as to reduce a leakage current, improve an operating frequency, and improve the proportion of devices produced which function correctly (yield).

In the semiconductor integrated circuit having the substrate voltage control function, a substrate voltage which is different from a voltage (a power supply voltage VDD or a ground voltage VSS) which is applied to a source terminal or the like during a normal operation, can be applied to substrate terminals of transistors provided in a standard cell, via a power supply wire which is a line separated from a power supply wire for the source terminal. Thereby, an effective threshold voltage of the transistor is changed, thereby making it possible to change the effective threshold voltage of the transistor without changing an impurity concentration of the semiconductor substrate.

By changing the absolute value of the effective threshold voltage, electrical characteristics of the transistor can be changed. For example, the leakage current can be reduced by increasing the absolute value of the effective threshold voltage. This is because a sub-threshold current which occupies most of the leakage current is proportional to exp(−|Vt|) where Vt is the effective threshold voltage and |Vt| is the absolute value of the effective threshold voltage. In addition, the switching speed of the transistor can be improved by reducing the absolute value of the effective threshold voltage. This is because, as the absolute value of the effective threshold voltage is reduced, the source-drain current is increased, so that the current drive performance of the transistor is improved.

Therefore, in the case of a configuration in which the absolute value of the effective threshold voltage can be increased, by temporarily increasing the absolute value of the effective threshold voltage of a transistor included in a circuit which is temporarily not used, of the transistors provided in a semiconductor integrated circuit, the leakage current can be reduced without an influence on the operating performance of the semiconductor integrated circuit, so that the power consumption of the semiconductor integrated circuit can be effectively reduced.

On the other hand, in the case of a configuration in which the absolute value of the effective threshold voltage can be decreased, by reducing the absolute value of the effective threshold voltage of a transistor for which a high-speed operation is required, the switching speed of the transistor is increased, thereby making it possible to increase the operating frequency of the semiconductor integrated circuit.

Further, in the case of a configuration in which the absolute value of the effective threshold voltage can be both increased and decreased, a variation in the threshold voltage of a transistor due to, for example, a variation in the concentration of an impurity implanted in the substrate during manufacture of the semiconductor integrated circuit, can be electrically corrected, depending on the variation. Thereby, a variation in threshold voltage occurring during manufacture can be corrected after the manufacture. Therefore, it is possible to reduce a probability that a transistor provided in the semiconductor integrated circuit has a performance departed from a range guaranteed by design, thereby making it possible to improve the yield of the semiconductor integrated circuit.

Hereinafter, two conventional examples relating to the standard cell for use in the semiconductor integrated circuit having the substrate voltage control function, will be described.

A first conventional example will be described. FIG. 12 illustrates a standard cell disclosed in U.S. Pat. No. 5,763,907.

In FIG. 12, the standard cell 100 comprises normal power supply wires 12 and 13 and a substrate power supply wire 15. The normal power supply wires 12 and 13 and the substrate power supply wire 15 each laterally extend from a left side to a right side of the standard cell 100, and each have a wiring width and a wiring position which are made common among different standard cells. Thereby, when standard cells are disposed laterally adjacent to each other, the normal power supply wires 12 and 13 and the substrate power supply wire 15 of one standard cell are electrically connected to the normal power supply wires 12 and 13 and the substrate power supply wire 15 of the other standard cell, respectively.

A voltage applied to the normal power supply wire 12 is a power supply voltage VDD, and the normal power supply wire 12 is connected to the sources of p-channel transistors provided in the standard cell 100. A voltage applied to the normal power supply wire 13 is a ground voltage VSS, and the normal power supply wire 13 is connected to the source terminals of n-channel transistors provided in the standard cell 100. In FIG. 12, the normal power supply wires 12 and 13 are connected to and the source terminals of the respective transistors through via holes 11 and 14, respectively.

The substrate power supply wire 15 is connected to the substrate terminals of the n-channel transistors provided in the standard cell 100. By applying a potential different from the ground voltage VSS to the substrate power supply wire 15, the effective threshold voltage of the n-channel transistor provided in the standard cell 100 can be changed. The substrate power supply wire 15 is connected to a diffusion layer through a via hole 16, thereby making it possible to apply a potential which is-different from that of the normal power supply wire 13, from the substrate power supply wire 15 to the substrate terminal of the n-channel transistor.

Next, a second conventional example will be described. FIG. 13 illustrates a standard cell disclosed in JP No. 2002-299450 A. The standard cell 170 comprises power supply terminals 2 and 3, diffusion layers 4 and 5, and polysilicon wires 6 and 7. The power supply terminal 3 is provided so as to supply the potential of a ground voltage VSS to the source terminal and the substrate of n-channel transistors. The power supply terminal 2 is provided so as to supply a power supply voltage VDD to the source terminal and the substrate of p-channel transistors.

The power supply terminals 2 and 3 each comprise a first-layer metal wire and a second-layer metal wire, and also, a via hole between the first-layer metal wire and the second-layer metal wire, and a via hole between a diffusion layer and the first-layer metal wire.

In addition, when standard cells are disposed laterally adjacent to each other, the power supply terminals 2 or the power supply terminals 3 of the standard cells are not electrically connected to each other.

However, the first conventional example has a low degree of design freedom, and the second conventional example has a large number of design steps.

Hereinafter, the above-described drawbacks will be described in detail.

Firstly, the low degree of design freedom which is a problem with the first conventional example will be hereinafter described in detail in terms of two points. The two points are a low degree of freedom for layout design of a standard cell itself, and a low degree of freedom for layout design of a semiconductor integrated circuit employing the standard cell. Hereinafter, each point will be described.

Firstly, the first point, i.e., the low degree of freedom for layout design of a standard cell, will be hereinafter described.

In the standard cell of the first conventional example, the substrate power supply wire 15 is previously fixedly disposed inside the standard cell. Therefore, no matter what logic is provided in the standard cell, there is a design constraint that, in a region in which the substrate power supply wire 15 is disposed, another metal wire in the same layer cannot be disposed. Due to the design constraint, there is a problem that the degree of freedom of layout of metal wires is low in layout design of a standard cell itself.

Next, the second point, i.e., the low degree of freedom for layout design of a semiconductor device employing the standard cell, will be hereinafter described.

When a semiconductor integrated circuit is designed using the standard cell of the first conventional example, the substrate power supply wire 15 is previously fixedly disposed inside the standard cell. Therefore, as described above, there is the design constraint that, in a region in which the substrate power supply wire 15 is disposed, another metal wire in the same layer cannot be disposed. Due to the design constraint, there is a problem that the degree of freedom of wiring is low in layout design of a semiconductor integrated circuit. Hereinafter, its specific example will be described.

FIG. 14 illustrates an exemplary semiconductor integrated circuit which employs standard cells of the first conventional example. Each standard cell 2500 is the standard cell of the first conventional example. A semiconductor integrated circuit 2599 includes a plurality of standard cell rows 2550, in each of which a plurality of standard cells 2500 having different functions are disposed in the same direction.

Also, normal power supply wires 13 and 12 and substrate power supply wires 15 of the standard cells 2500 are connected to each other, respectively, by disposing the standard cells laterally adjacent to each other, thereby constituting inter-cell normal power supply wires 2504 and 2505 and an inter-cell substrate power supply wire 2503, respectively. The inter-cell normal power supply wires 2504 and 2505 and the inter-cell substrate power supply wire 2503 are connected to normal power supply strap wires 2542 and 2541 and a substrate power supply strap wire 2540, respectively.

The inter-cell normal power supply wires 2504 and 2505 and the inter-cell substrate power supply wire 2503 are also connected via the normal power supply strap wires 2542 and 2541 and the substrate power supply strap wire 2540, respectively, to a current supply source external to the semiconductor integrated circuit 2599.

The semiconductor integrated circuit 2599 further comprises a hardmacro 2510. The hardmacro 2510 comprises output buffers 2531 and 2511, which are connected to signal wires 2532 and 2512, respectively, whereby signals output from the output buffers 2531 and 2511 are propagated through the signal wires 2532 and 2512, respectively.

A wiring direction of the signal wire 2532 is parallel to the standard cell row 2550, and a wiring layer forming the signal wire 2532 is different from a wiring layer forming the inter-cell substrate power supply wire 2503.

The output buffer 2531 is provided so as to propagate a signal to the outside of the hardmacro 2510, and has a high level of drive performance.

In the configuration, in a region 2520 of FIG. 14, the signal wire 2532 and the inter-cell substrate power supply wire 2503 are disposed parallel to each other, and are close to each other or overlap, so that crosstalk noise causes glitch or a change in signal transfer timing. In this case, the inter-cell substrate power supply wire 2503 is a victim which is affected by the crosstalk noise, while the signal wire 2532 is an aggressor which produces the crosstalk noise. This is a phenomenon in which a voltage change ΔV occurring in the aggressor leads to a charge amount change ΔQ occurring in the victim via a parasitic capacitance C between the two wires (the aggressor and the victim), and a relationship ΔQ=C×ΔV is established. The voltage change ΔV is inversely proportional to a slew of a voltage signal waveform propagating through the aggressor. While a signal propagating through the signal wire 2532 has a small slew due to the high level of drive performance of the output buffer 2531, a signal propagating through the inter-cell substrate power supply wire 2503 has a large slew. This is because a high-speed operation is generally not required to change the effective threshold voltage using a substrate voltage control technique, and also, after the substrate power supply voltage once becomes stable, a current corresponding to the leakage current may be supplied from the substrate power supply wire, and the substrate power supply wire has a large wire capacitance. Therefore, the slew is smaller in the signal wire 2532 than in the inter-cell substrate power supply wire 2503, so that the signal wire 2532 is an aggressor.

In addition, an influence of noise occurring in the victim due to the charge amount change ΔQ increases with a decrease in the current drive performance of the current supply source for driving the victim. This is because a time required to absorb a change in potential occurring due to the charge amount change ΔQ increases with a decrease in the current drive performance. Noise propagates as glitch in the victim wire, so that a terminal voltage of a transistor connected to the victim wire is changed. As a result, an operation of the transistor is affected.

Here, in the inter-cell substrate power supply wire 2503 (victim), as described above, a high-speed operation is generally not required or the like, the current drive performance of the current supply source is smaller than in the signal wire 2532. Therefore, the influence of noise occurring in the inter-cell substrate power supply wire 2503 is larger.

Thus, the inter-cell substrate power supply wire 2503 becomes a victim, and therefore, a voltage change due to glitch, which leads to crosstalk noise, occurs, so that the substrate terminal voltage of a transistor connected to the inter-cell substrate power supply wire 2503 changes, and the threshold voltage of the transistor changes. If the threshold voltage of the transistor changes, the current drive performance and the switching characteristics of the transistor change. In this case, a signal propagation speed of a propagation route via the transistor changes, so that timing violation is likely to occur. As a result, a failure in signal transfer on a route having timing violation causes an incorrect operation of the semiconductor integrated circuit to be likely to occur, leading to a reduction in manufacturing yield.

To avoid this, the wiring route of the signal wire 2532 or the substrate power supply wire 2503 may be changed. However, the inter-cell substrate power supply wire 2503 is previously fixedly disposed in the standard cell 2500, so that the wiring route cannot be changed. Therefore, a wiring route of the signal wire 2532 is only changed. Thus, in the semiconductor integrated circuit employing the standard cell of the first conventional example, since the substrate power supply wire 15 is previously fixed, the degree of freedom of design is low, and the option of changing wiring is limited as described above.

Note that the signal wire 2532 is also disposed parallel to the inter-cell normal power supply wires 2505 and 2504, however, the inter-cell normal power supply wires 2505 and 2504 need to supply an operating current to transistors, and drive a large current with high speed, so that it is difficult for the inter-cell normal power supply wires 2505 and 2504 to be victims, and therefore, the inter-cell normal power supply wires 2505 and 2504 are unlikely to be affected by the influence of crosstalk. Therefore, the inter-cell normal power supply wires 2505 and 2504 can be excluded from discussion about the occurrence of timing violation.

Next, the number of design steps which is a problem with the second conventional example will be hereinafter described in detail.

When the standard cell of the second conventional example is used to design a semiconductor integrated circuit, since a power supply voltage is applied to transistors, a normal power supply wire needs to be disposed in the semiconductor integrated circuit. The normal power supply wire is used to connect the power supply terminals 2 and 3 provided in the standard cell to a power supply wire network provided in the semiconductor integrated circuit, however, in the standard cell of the second conventional example, the normal power supply wire is not fixedly disposed in the standard cell, as is different from the first conventional example. Therefore, in the wiring step for the semiconductor integrated circuit, not only a signal wire for connecting a signal input terminal and a signal output terminal of the standard cell, but also a normal power supply wire need to be disposed.

However, since the normal power supply wire needs to supply a current to a number of transistors connected thereto, the normal power supply wire often has a width larger than that of the signal wire. Here, in the case of the wire having the large width, a wiring interval between adjacent metal wires may be larger than that in the case of narrower wires.

Note that the reason why the wiring interval is set to be wide is as follows. In the flattening step for a semiconductor integrated circuit, an insulator (oxide film) immediately after polishing by CMP (Chemical Mechanical Polish), has a convex shape which is weak to mechanical stress and is easily broken. Particularly, an insulator adjacent to a metal wire having a larger width has a higher convex protruding portion which is a shape which is easily broken. Therefore, the wiring interval needs to be designed to be wide, depending on the wiring width of an adjacent metal wire, so that a width of the protruding portion is set, depending on a height of the protruding portion, thereby providing a shape having a stress which resists breakage, to the convex structure of the insulator after CMP.

Note that, in the wiring step in layout design for a semiconductor integrated circuit, when a wire having a large width or a large wiring interval is mixed, a more complicated process is required and a longer time until the end of the whole process is required than when the width and the wiring interval are uniform. The wiring area of a single wire having a large width or interval (hereinafter referred to as a wide wire) corresponds to the area of several or tens and several wires having not a large width or interval (hereinafter referred to as fine wires). Therefore, the wide wire has a larger influence on a surrounding than that of the fine wire when a wiring route is optimized, so that, when the wiring route of a single wide wire is optimized, a larger number of surrounding wires need to be changed. This means that there are a larger number of parameters which should be taken into consideration when a single wire is optimized, and therefore, a time required to optimize all of the parameters is increased.

### SUMMARY OF THE INVENTION

To solve the above-described problems, an object of the present invention is to provide a standard cell which is configured so that, when a semiconductor integrated circuit is designed using a plurality of standard cells having a substrate voltage control function, a normal power supply wire network can be formed only by disposing the standard cells, and a wiring route of an inter-cell substrate power supply wire can be free set.

Specifically, the present invention provides a standard cell comprising a normal power supply wire for supplying a power supply voltage to sources of transistors, and a substrate power supply wire for supplying a substrate power supply voltage to a substrate of the transistors. The normal power supply wire is composed of a fixed wire whose position in a height direction and wiring width are set to be the same as those of another standard cell of a kind different from that of the standard cell, and which is disposed across the standard cell in a direction perpendicular to the height direction. The substrate power supply wire is composed of a non-fixed wire different from the fixed wire.

In one example of the standard cell of the present invention, when the standard cell is disposed adjacent to another standard cell, the non-fixed wire is not connected to a non-fixed wire of the other standard cell.

In one example of the standard cell of the present invention, the non-fixed wire is provided in each of an n-well region and a p-well region.

In one example of the standard cell of the present invention, a plurality of the non-fixed wires are provided.

In one example of the standard cell of the present invention, the non-fixed wire is a substrate power supply terminal for supplying the substrate power supply voltage.

In one example of the standard cell of the present invention, the substrate power supply terminal is provided in each of an n-well region and a p-well region.

In one example of the standard cell of the present invention, a plurality of the substrate power supply terminals are provided.

The present invention also provides a standard cell library comprising the standard cell of the present invention.

The present invention also provides a semiconductor integrated circuit comprising the standard cell of the present invention.

The present invention also provides a semiconductor integrated circuit composed of a plurality of standard cell rows including a plurality of standard cells, comprising a normal power supply wire network for supplying a power supply voltage to sources of transistors included in each standard cell, and a substrate power supply wire network for supplying a substrate power supply voltage of a substrate of the transistors of each standard cell. The normal power supply wire network includes a fixed inter-cell wire disposed in a width direction along each standard cell row. The substrate power supply wire network includes a non-fixed inter-cell wire different from the fixed inter-cell wire.

In one example of the semiconductor integrated circuit of the present invention, the non-fixed inter-cell wire is composed of a plurality of wires for supplying the substrate power supply voltage to each of an n-well region and a p-well region of each standard cell.

In one example of the semiconductor integrated circuit of the present invention, the non-fixed inter-cell wire is configured by connecting substrate power supply terminals provided in the standard cells.

In one example of the semiconductor integrated circuit of the present invention, the non-fixed inter-cell wire is configured by connecting a portion of substrate power supply terminals provided in the standard cells.

In one example of the semiconductor integrated circuit of the present invention, the normal power supply wire network comprises a normal power supply strap wire which is disposed in a direction perpendicular to the fixed inter-cell wire and is connected to the fixed inter-cell wire.

In one example of the semiconductor integrated circuit of the present invention, the substrate power supply wire network comprises a substrate power supply strap wire which is disposed parallel to the normal power supply strap wire and is connected to the non-fixed inter-cell wire.

In one example of the semiconductor integrated circuit of the present invention, the substrate power supply strap wire has a wiring width larger than that of the non-fixed inter-cell wire.

The present invention also provides a semiconductor integrated circuit including a number of transistors, comprising a normal power supply wire network for supplying a power supply voltage to a source of each transistor, a substrate power supply wire network for supplying a substrate power supply voltage to a substrate of each transistor, and a plurality of signal wires. The normal power supply wire network is disposed, extending in a predetermined wiring layer in a single direction. The substrate power supply wire network is disposed in a plurality of wiring layers in a plurality of directions so as to circumvent the normal power supply wire network and the plurality of signal wires.

Thus, according to the present invention, although the standard cell has a substrate power supply wire, the substrate power supply wire does not extend across the standard cell in the width direction, so that an empty region occurs, and therefore, a metal wire of the same layer can be disposed in this region. Thereby, the degree of freedom of layout design for a standard cell can be improved.

In addition, when a semiconductor integrated circuit is designed by disposing other standard cells adjacent to the standard cell, an inter-cell substrate power supply wire is not formed only by disposing the adjacent cells, and it is necessary to additionally dispose inter-cell substrate power supply wires connecting substrate power supply wires in a plurality of standard cells individually. In this case, the wiring route of the inter-cell substrate power supply wire can be freely set and changed so that crosstalk does not occur between a signal wire already disposed and the inter-cell substrate power supply wire, resulting in a high degree of freedom of layout design for a semiconductor integrated circuit.

In addition, since a normal power supply wire is previously fixedly disposed in a standard cell, when a semiconductor integrated circuit is designed, inter-cell normal power supply wires do not need to be disposed individually. Therefore, wide wires (normal power supply wires) do not need to be disposed individually, so that the wide wires and fine wires are not mixed in the wiring step, and therefore, a simpler wiring state should be taken into consideration in the wiring step, so that a design step can be completed in a shorter time.

Although, as described above, the inter-cell substrate power supply wire is taken into consideration when a semiconductor integrated circuit is designed, the substrate power supply wire has a wiring width similar to that of signal wires since a high-speed operation is generally not required or the like, so that a wide wire and a fine wire are not mixed in the wiring step.

### BRIEF DESCRIPTION OF THE DRAWINGS

FIG. 1A is a schematic diagram illustrating a standard cell according to a first example of the present invention. FIG. 1B is a cross-sectional view illustrating a major portion of a variation of a substrate power supply wire in the standard cell.

FIG. 2 is a schematic diagram when two standard cells of FIG. 1A are disposed adjacent to each other in a width direction.

FIG. 3 is a schematic diagram illustrating a variation of the standard cell.

FIG. 4 is a diagram illustrating a semiconductor integrated circuit according to a second example of the present invention.

FIG. 5 is a cross-sectional view of the semiconductor integrated circuit, taken along line IV-IV of FIG. 4.

FIG. 6 is a diagram illustrating a configuration of a semiconductor integrated circuit when a wiring route of an inter-cell substrate power supply wire is determined, depending on the density of wires.

FIG. 7 is a diagram illustrating a semiconductor integrated circuit according to a third example of the present invention.

FIG. 8 is a flowchart of a method for designing a layout of a semiconductor integrated circuit according to a fourth example of the present invention.

FIG. 9 is a schematic diagram of a semiconductor integrated circuit before wiring.

FIG. 10 is a schematic diagram illustrating a semiconductor integrated circuit obtained by performing a signal wire wiring step with respect to a semiconductor integrated circuit before wiring.

FIG. 11 illustrates a semiconductor integrated circuit designing apparatus according to a sixth example of the present invention.

FIG. 12 is a diagram illustrating a standard cell having a substrate control function according to conventional example 1.

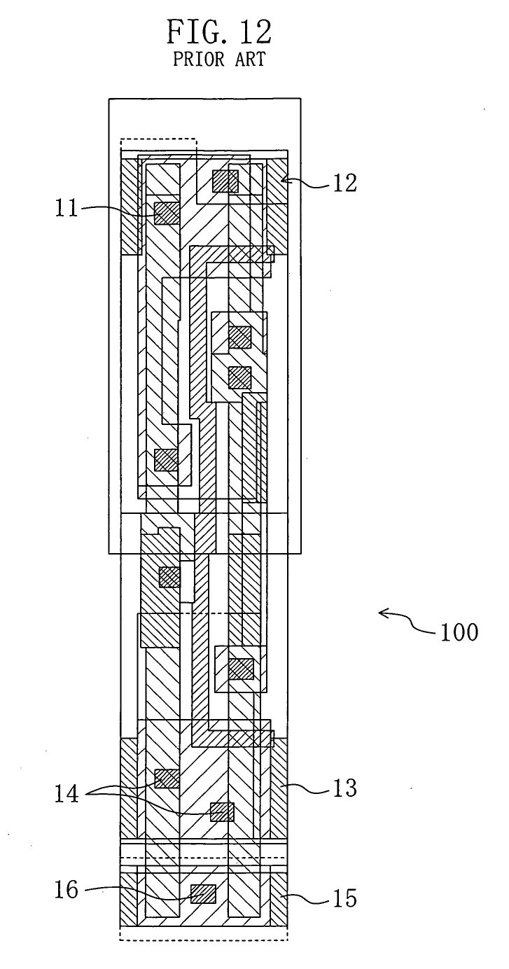

FIG. 13 is a diagram illustrating a standard cell having a power supply terminal according to conventional example 2.

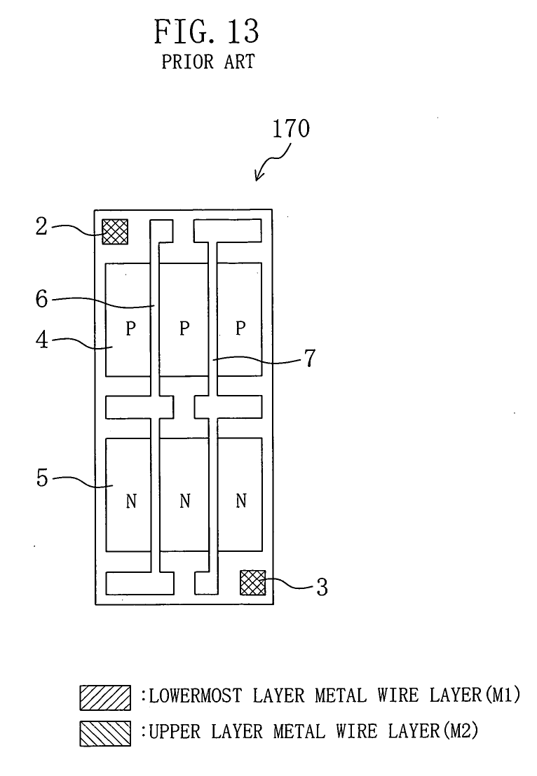

FIG. 14 is a diagram illustrating an exemplary semiconductor integrated circuit configured using the standard cells of conventional example 1.

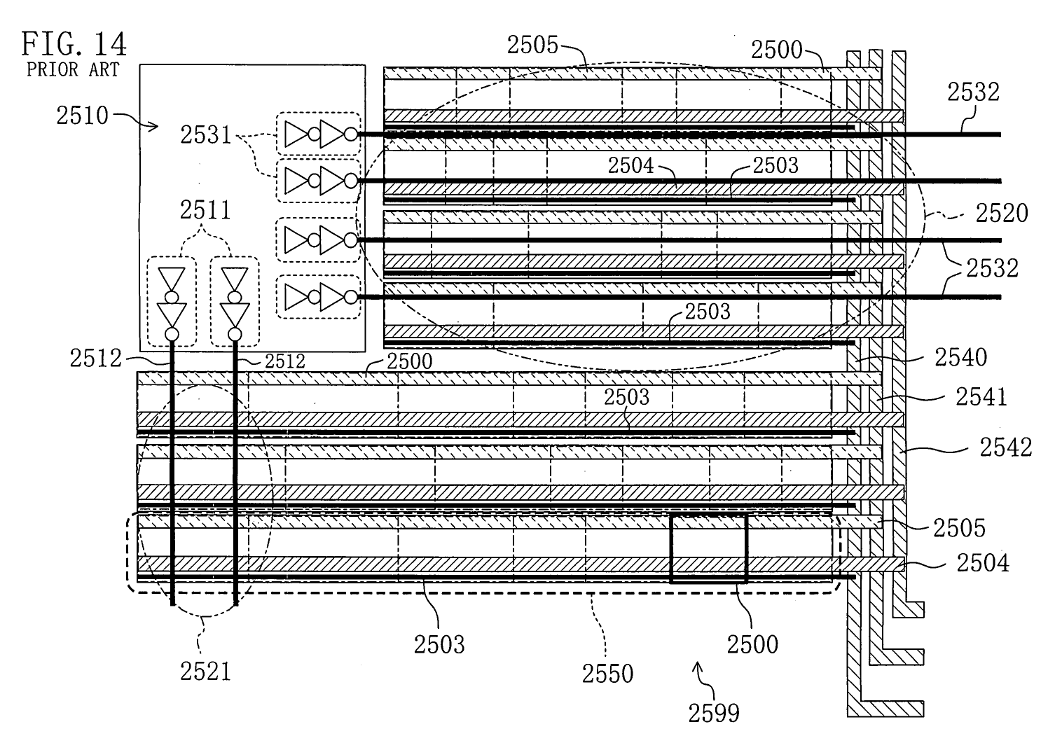

### DETAILED DESCRIPTION OF THE PROFFERED EMBODYMENTS

Hereinafter, preferred embodiments of the present invention will be described with reference to the accompanying drawings.

### FIRST EXAMPLE

Hereinafter, examples of the present invention will be described with reference to the drawings.

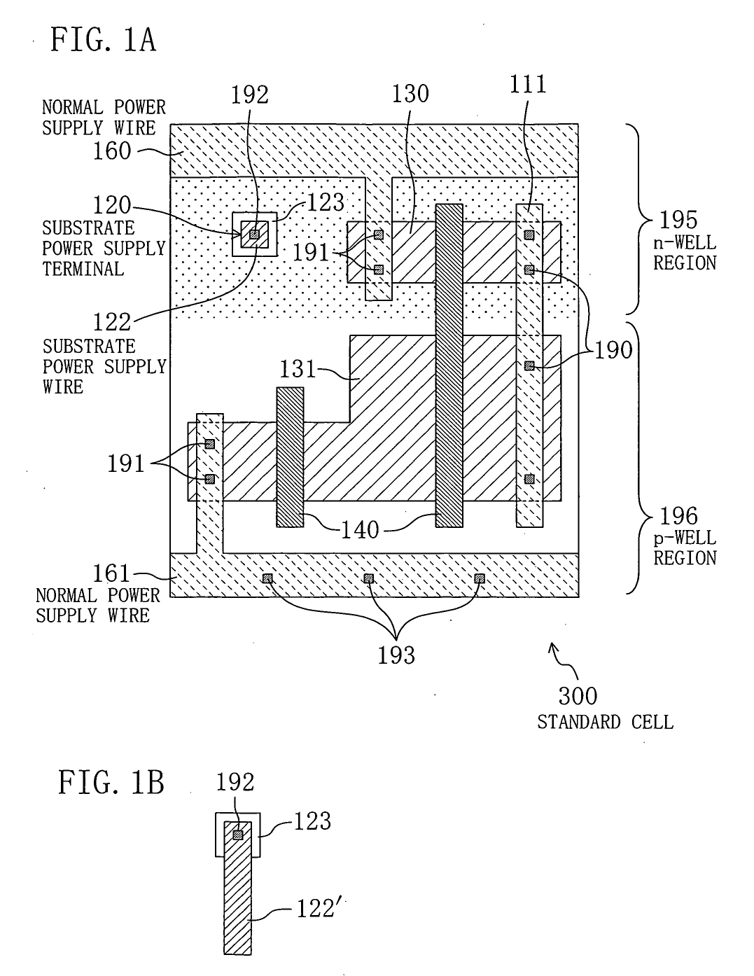

FIG. 1A illustrates an exemplary standard cell of the present invention. In FIG. 1A, the standard cell 300 is divided into two upper and lower portions, i.e., an n-well region 195 and a p-well region 196. Diffusion layers 130 and 131 are provided in the n-well region 195 and the p-well region 196, respectively. A polysilicon wire 140 is provided on each of the diffusion layers 130 and 131. Also, the polysilicon wire 140 functions as the gates of transistors on each of the diffusion layers 130 and 131. The diffusion layers 130 and 131 are connected through via holes 190 to a metal wire 111. The standard cell 300 also comprises normal power supply wires 160 and 161, and a substrate power supply terminal 120.

The normal power supply wires 160 and 161 are each a metal wire and are each disposed, extending laterally from a left side to a right side. From the normal power supply wires 160 and 161, metal wires are extend to overlap the diffusion layers 130 and 131, respectively, and are connected through via holes 191 to the diffusion layers 130 and 131, respectively. A predetermined power supply voltage VDD and a ground voltage VSS are applied to the normal power supply wires 160 and 161, respectively.

A region in which an impurity having a polarity different from that of a surrounding substrate portion is implanted, is provided in the substrate immediately below or in the vicinity of the normal power supply wire 161. The region is connected to the normal power supply wire 161 through via holes 193.

The substrate power supply terminal 120 is composed of a substrate power supply wire 122 (metal wire). A region 123 in which an impurity having a polarity different from that of a surrounding portion of the substrate is formed in the substrate immediately below or in the vicinity of the substrate power supply terminal 120. The region 123 is connected to the substrate power supply terminal 120 (the substrate power supply wire 122) through a via hole 192. The power supply voltage VDD or a potential different therefrom is applied to the substrate power supply terminal 120 as described below.

The normal power supply wires 160 and 161 have the same position in a length direction (position in a height direction) and the same wiring width even among different kinds of standard cells, and are composed of a common fixed wire disposed, extending across the standard cell to which the normal power supply wires 160 and 161 belong, in a direction perpendicular to the height direction, i.e., a width direction.

The substrate power supply terminal 120 (the substrate power supply wire 122) do not have a common structure as seen in the normal power supply wires 160 and 161, among different kinds of standard cells.

Note that the substrate power supply terminal 120 can be replaced with a substrate power supply wire 122′ illustrated in FIG. 1B. Specifically, in FIG. 1A, although the substrate power supply wire 122 is in the shape of a plane quadrangular terminal, the substrate power supply wire 122′ of FIG. 1B is in the shape of a rectangle extending downward in FIG. 1B from an upper portion of the region 123. The substrate power supply terminal 120 and the substrate power supply wire 122 do not necessarily have the same position in the height direction (length direction) or the same wiring width among different kinds of standard cells, as is different from the normal power supply wires 160 and 161, and may be non-fixed wires which do not have a common structure in which a wire is disposed, extending across a standard cell to which the wires belong in the width direction.

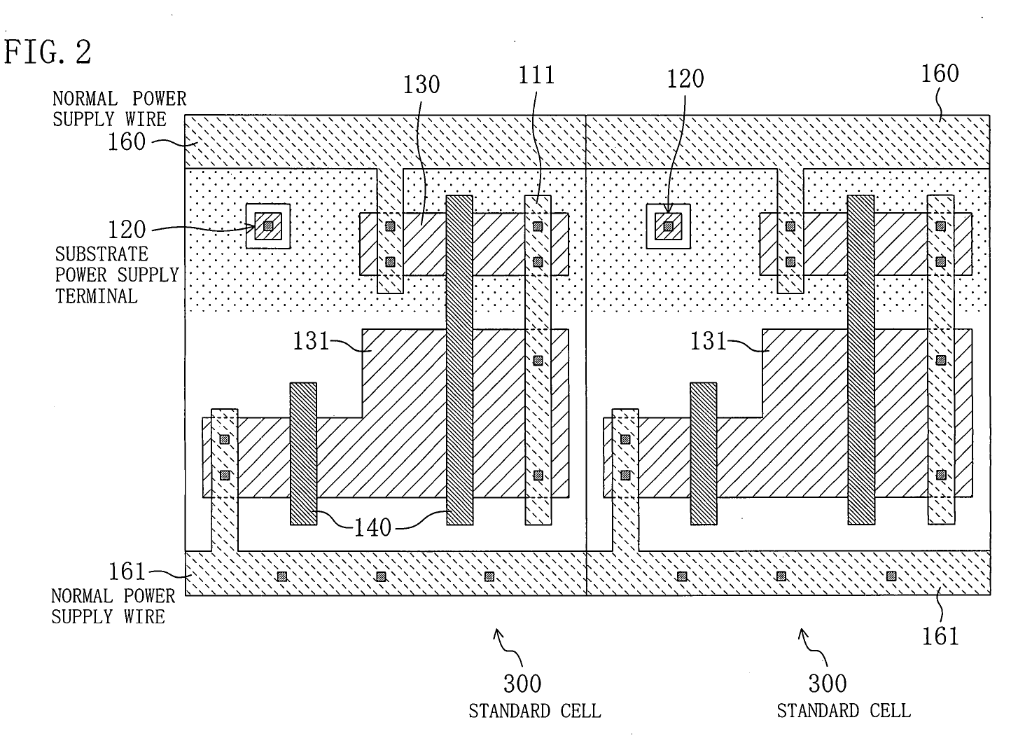

FIG. 2 is a schematic diagram when two standard cells 300 of FIG. 1 are disposed adjacent to each other in the width direction. Since the normal power supply wires 160 and 161 have the common fixed structure as described above, the normal power supply wires 160 and 161 are electrically connected to each other in the two standard cells 300 disposed adjacent to each other in the width direction. On the other hand, the substrate power supply terminals 120 are not connected to each other.

Note that, in FIGS. 1A and 2, metal wires or polysilicon wires corresponding to a signal input terminal and a signal output terminal, a metal wire or a polysilicon wire for electrically connecting the polysilicon wire 140 and the signal input terminal, and the like will not be described for the sake of simplicity.

Hereinafter, the standard cell thus constructed will be described.

The substrate power supply terminal 120 is a wire having a non-fixed structure in which the position in the height direction and the wiring width are not necessarily the same as those of other kinds of standard cells, as is different from the normal power supply wires 160 and 161, and does not have a wire extending across from the left side to the right side of the standard cell 300. With this configuration, the degree of freedom of layout design for the substrate power supply wire is increased when the standard cell 300 is used. Specifically, since the substrate power supply wire can be provided by freely connecting the substrate power supply terminals 120 of adjacent standard cells 300, wiring can be freely performed as in the case of other signal wires. Thus, the degree of freedom of layout design can be improved using the standard cell 300, so that flexible design can be performed so as to improve speed, area, power consumption, and the like.

Note that, in this example, there is only one substrate power supply terminal 120 which is provided so as to apply a voltage to the substrate terminal of p-channel transistors, or alternatively, only a substrate power supply terminal which applies a voltage to the substrate terminal of n-channel transistors may be provided, or a substrate power supply terminal may be provided separated from the substrate terminal of each of both the p-channel and n-channel transistors.

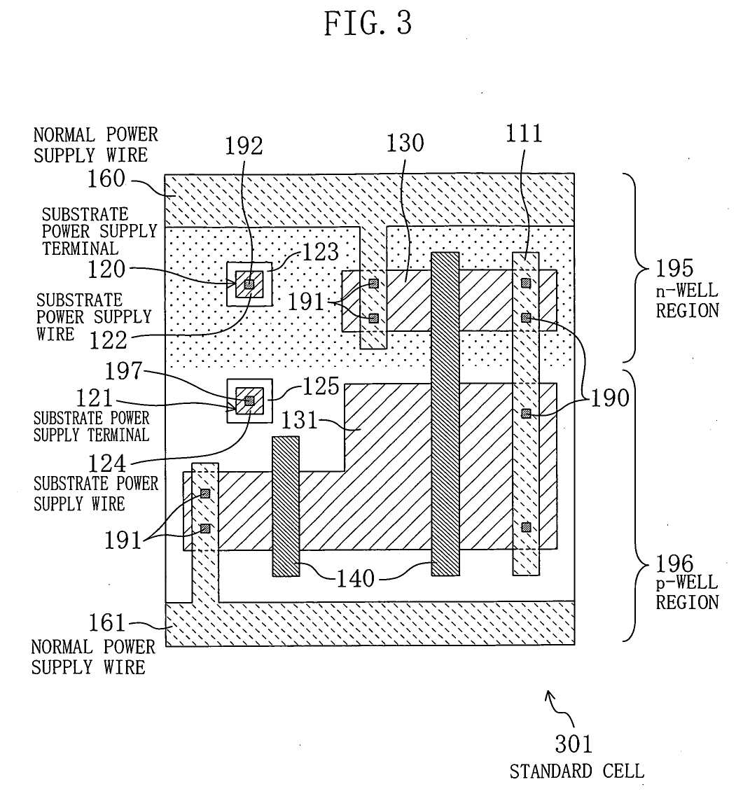

FIG. 3 is a schematic diagram illustrating a standard cell having a separate substrate power supply terminal for the substrate terminal of each of transistors having both polarities. In FIG. 3, the same parts as those of FIG. 1A are indicated by the same reference numerals. A standard cell 301 comprises two substrate power supply terminals 120 and 121. The substrate power supply terminal 120 and the substrate power supply terminal 121 are provided in the n-well region 195 and the p-well region 196, respectively, and are composed of the substrate power supply wires 122 and 124 (metal wires), respectively. Regions 123 and 125 in which an impurity having a polarity different from a surrounding substrate portion is implanted, are provided in the substrate in the vicinity of the substrate power supply terminals 120 and 121, respectively. The regions 123 and 125 are connected to the substrate power supply terminals 120 and 121 through via holes 192 and 197, respectively. The power supply voltage VDD or a potential different therefrom is applied to the substrate power supply terminal 120, and the ground voltage VSS or a potential different therefrom is applied to the substrate power supply terminal 121. Note that the via hole 193 is not provided, as is different from FIG. 1A.

With the above-described configuration, in the standard cell 301, a substrate power supply voltage is applied to the substrate terminal of the p-channel transistors from the substrate power supply terminal 120, and a substrate power supply voltage is applied to the substrate terminal of the n-channel transistors from the substrate power supply terminal 121, separately. Therefore, effective threshold voltages for the transistors having both polarities can be controlled separately using a substrate voltage control technique. Thereby, the substrate power supply voltage can be controlled more effectively than when only the substrate terminal of transistors having one polarity can be controlled.

Note that the numbers of substrate power supply terminals 120 or 121 provided in the standard cell 301 may be one or plural. Particularly in a standard cell having a large area, by providing and distributing a plurality of each of the substrate power supply terminals 120 and 121 in a standard cell, it is possible to suppress a variation in substrate potential in the standard cell, depending on the place.

The number of wiring layers forming the normal power supply wire 160 or 161 may be one or plural. The number of kinds of wiring layers forming the substrate power supply terminal 120 or 121 may be one or plural. In addition, the number of via holes for connecting the substrate power supply terminals 120 or 121 and the substrate is one as described above, or may be plural. Further, the number and connection of polysilicon wires 140 included in the standard cell 300 or 301, the number and shape of diffusion layer regions 130 or 131, and the number and shape of via holes connected to the diffusion layer 130 or 131, are not limited.

### SECOND EXAMPLE

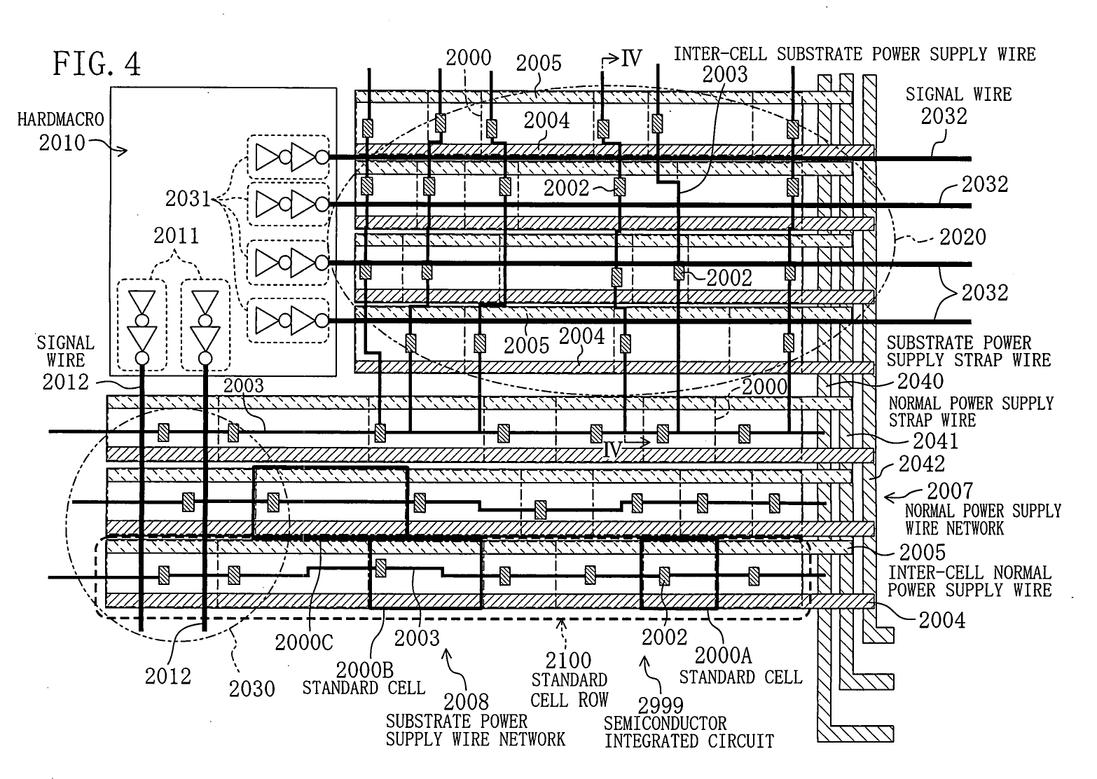

FIG. 4 illustrates a semiconductor integrated circuit according to a second example of the present invention.

In FIG. 4, the semiconductor integrated circuit 2999 includes a plurality of standard cell rows 2100 (only seven rows are illustrated in FIG. 4), each of which includes a plurality of standard cells 2000A, 2000B, 2000C, . . . disposed in the same direction (the width direction in FIG. 4). The standard cells 2000A, 2000B, 2000C, . . . have different internal structures, but as illustrated in FIG. 1A, have a common structure in that the normal power supply wires 160 and 161 have the same height position and the same wiring width among the standard cells, and extend in the width direction and disposed into a left side and a right side, and on the other hand, the substrate power supply terminals 120 and 121 are not necessarily formed at the same height position among the standard cells, and are isolated inside not to be disposed into the left side or the right side.

A pair of normal power supply wires 160 and 161 are provided in each of the standard cells 2000. The normal power supply wires 160 and 161 in adjacent standard cells are disposed laterally adjacent to each other, forming inter-cell normal power supply wires 2004 and 2005, respectively. As can be seen from FIG. 4, the inter-cell normal power supply wires (fixed inter-cell wires) 2004 and 2005 in the standard cell rows are disposed in a width direction of FIG. 4 along each standard cell row. The inter-cell normal power supply wires 2004 and 2005 constitute a normal power supply wire network 2007.

In FIG. 4, substrate power supply terminals 2002 in the standard cells 2000 adjacent in the width or length direction are connected to each other via inter-cell substrate power supply wires 2003. As can be seen from FIG. 4, the inter-cell substrate power supply wires 2003 are disposed both in the width direction extending along the standard cell rows, and the length direction perpendicular to the width direction. The substrate power supply terminals 2002 and the inter-cell substrate power supply wires (non-fixed inter-cell wires) 2003 of the standard cells 2000 constitute a substrate power supply wire network 2008.

The inter-cell normal power supply wires 2004 and 2005 are connected to normal power supply strap wires 2042 and 2041 disposed in the length direction perpendicular to the width direction in which the inter-cell normal power supply wires 2004 and 2005 extend, respectively. The inter-cell substrate power supply wire 2003 is connected to a substrate power supply strap wire 2040 disposed parallel to the normal power supply strap wires 2042 and 2041. As can be seen from FIG. 4, the substrate power supply strap wire 2040 has a wiring width larger than that of the inter-cell substrate power supply wire 2003, and substantially equal to that of the normal power supply strap wires 2042 and 2041.

The inter-cell normal power supply wires 2004 and 2005 and the inter-cell substrate power supply wire 2003 are connected via the normal power supply strap wires 2042 and 2041 and the substrate power supply strap wire 2040, respectively, to a current supply source external to the semiconductor integrated circuit 2999.

The semiconductor integrated circuit 2999 comprises a hardmacro 2010. The hardmacro 2010 comprises output buffers 2031 and 2011, and are connected to signal wires 2032 and 2012, respectively. Thereby, signals output from the output buffers 2031 and 2011 are propagated through the signal wires 2032 and 2012, respectively.

The signal wire 2032 has a wiring direction parallel to the standard cell row 2100. The output buffer 2031 is provided so as to propagate a signal to the outside of the hardmacro 2010, and has a high level of drive performance.

The inter-cell substrate power supply wires 2003 connect the substrate power supply terminals 2002 of standard cells 2000 adjacent to each other in the width direction or in the length direction, individually. As is different from the inter-cell normal power supply wires 2004 and 2005, the direction of the wiring route of the inter-cell substrate power supply wire 2003 is flexibly changed into the width direction or the length direction, depending on a surrounding wiring state. Also, the inter-cell substrate power supply wire 2003 has the same width as that of other signal wires.

In regions 2030 and 2020 in which the inter-cell substrate power supply wire 2003 and the signal wires 2012 and 2032 are positioned close to each other, the inter-cell substrate power supply wire 2003 does not run parallel to the signal wires 2012 and 2032, and the wiring direction of the inter-cell substrate power supply wire 2003 is changed so that the inter-cell substrate power supply wire 2003 is perpendicular to the signal wires 2012 and 2032.

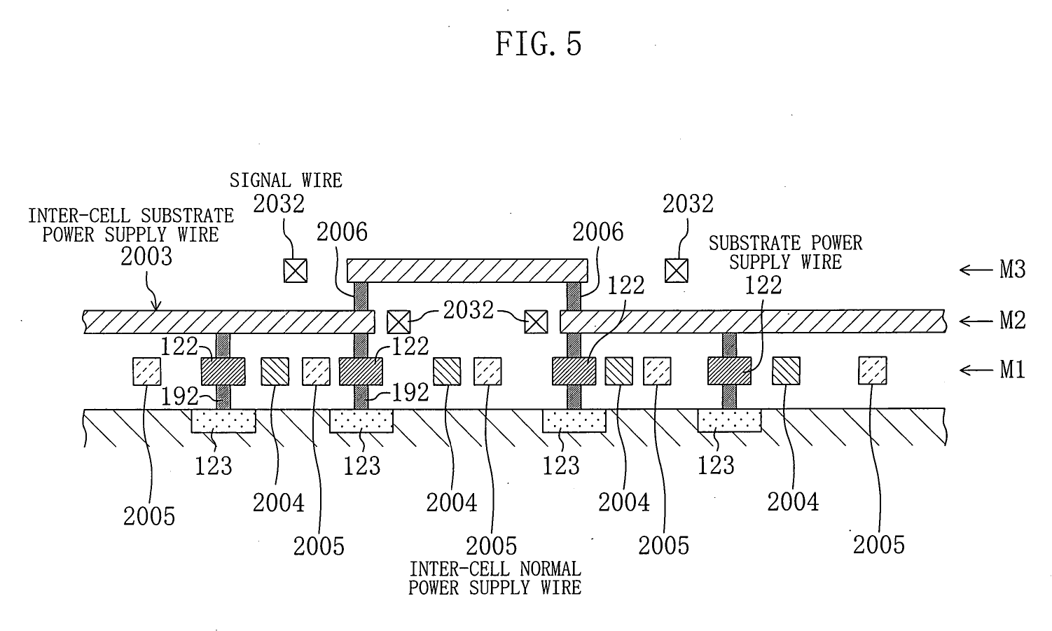

FIG. 5 is a cross-sectional view of the semiconductor integrated circuit, taken along line IV-IV of FIG. 4. As can be seen from FIG. 5, the inter-cell normal power supply wires 2004 and 2005 are disposed, extending in a single direction only in a first wiring layer M1. On the other hand, the inter-cell substrate power supply wire 2003 is disposed both in a second wiring layer M2 and a third wiring layer M3 through via holes 2006 while circumventing the normal power supply wires 2004 and 2005 and the signal wire 2032, and as can be seen from FIG. 4, are disposed parallel or perpendicular to the inter-cell normal power supply wires 2004 and 2005.

The semiconductor integrated circuit thus constructed will be hereinafter described.

The wiring route of the inter-cell substrate power supply wires 2003 is not previously fixed, and the inter-cell substrate power supply wires 2003 are configured to connect the substrate power supply terminals 2002 individually, so that the wiring route of the inter-cell substrate power supply wires 2003 can be changed, depending on the wiring route of signal wires. Thereby, the wiring route can be changed as appropriate, depending on the state of wires surrounding the inter-cell substrate power supply wire 2003 (a state of occurrence of crosstalk noise between the inter-cell substrate power supply wire 2003 and a surrounding wire, the density of wires, etc.), resulting in an increase in the degree of design freedom.

In this example, the inter-cell substrate power supply wire 2003 extends in the width direction in the region 2030 of FIG. 4, and in the length direction in the region 2020. This is because, for example, in the region 2020, if the inter-cell substrate power supply wire 2003 were disposed in the width direction, crosstalk noise is caused in the inter-cell substrate power supply wire 2003 since the inter-cell substrate power supply wire 2003 and the which is signal wire 2032 run parallel to each other over a large length, and therefore, to avoid this, the wiring route is changed from the width direction to the length direction so that the inter-cell substrate power supply wire 2003 is perpendicular to the signal wire 2032.

Thus, in a portion where a signal wire which is driven by a cell having a high level of drive performance, the wiring route of the substrate power supply wire 2003 is determined so that the substrate power supply wire 2003 is not disposed parallel to a signal wire, thereby making it possible to avoid occurrence of crosstalk noise to the substrate power supply wire 2003 due to parallel wiring. Thereby, it is possible to prevent glitch from occurring in the substrate power supply wire 2003 to suppress a variation in effective threshold voltage of a transistor due to glitch, and suppress the probability of occurrence of an incorrect operation, resulting in an improvement in yield.

The normal power supply wire is composed of the inter-cell normal power supply wires 2004 and 2005, and is previously fixedly provided, so that the normal power supply wires can be electrically connected only by disposing standard cells adjacent to each other, and therefore, the wiring of the normal power supply wires is not additionally required. A wire having a large width or a large wiring interval does not need to be mixed, so that the number of steps required for wiring is not increased.

Although the substrate power supply wire 2003 is not previously fixed in a standard cell in this example, since the wiring width of the substrate power supply wire 2003 is substantially the same as that of signal wires as described above, the above-described complexity does not occur.

Although crosstalk noise has been described in detail as a factor for determining the wiring route of the inter-cell substrate power supply wire 2003 in this example, the wiring route of the inter-cell substrate power supply wire 2003 may be determined, depending on the density of wires surrounding the inter-cell substrate power supply wire 2003, or the like.

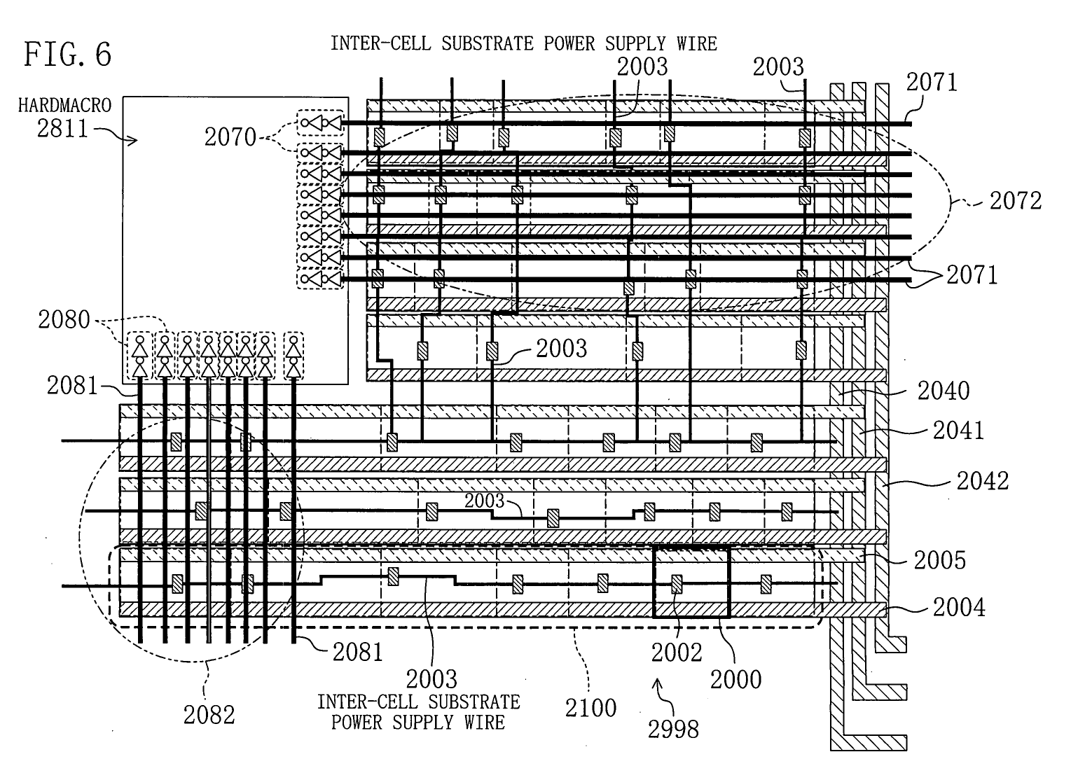

FIG. 6 illustrates an exemplary semiconductor integrated circuit when the wiring route of the inter-cell substrate power supply wire 2003 is determined, depending on the density of wires.

In FIG. 6, a hardmacro 2811 comprises input buffers 2070 and 2080, which are connected to signal wires 2071 and 2081, respectively. The signal wire 2071 is disposed in the width direction, while the signal wire 2081 is disposed in the length direction.

In FIG. 6, a region 2072 is a region in which the signal wire 2071 is disposed, and the density in the width direction of wires in the region 2072 is increased by the signal wire 2071. On the other hand, a region 2082 is a region in which the signal wire 2081 is disposed, and the density in the length direction of wires in the region 2082 is increased by the signal wire 2081.

In the region 2072, the inter-cell substrate power supply wire 2003 is disposed, extending in the length direction in which the density of wires is low, and, in the region 2082, the inter-cell substrate power supply wire 2003 is disposed, extending in the width direction in which the density of wires is low.

Thus, the wiring route of the inter-cell substrate power supply wire 2003 is changed, depending on the wire density, thereby making it possible to prevent a drawback that, as the wire density is increased, it becomes not possible to achieve wiring or the area increases.

Although it is illustrated in this example that a single substrate power supply terminal 2002 is provided in each standard cell 2000, a plurality of substrate power supply terminals 2002 may be provided. Particularly in a standard cell having a large area, if a plurality of substrate power supply terminals 2002 are provided and distributed in the standard cell, a variation in substrate potential in the standard cell can be further suppressed.

The inter-cell substrate power supply wire 2003 may be composed only of a metal wire in a single wiring layer, or a metal wire in a plurality of wiring layers. When there are two substrate power supply terminals 2002 in the standard cell 2000 (one for each of the n-well region and the p-well region), two inter-cell substrate power supply wires 2003 are necessarily disposed for the two substrate power supply terminals 2002 individually.

Although there are two inter-cell normal power supply wires 2004 and 2005 in this example, there may be three or more power supply wires 2004 and 2005. Also, although the normal power supply strap wires 2041 and 2042 and the substrate power supply strap wire 2040 are employed in this example, none of them may be used.

### THIRD EXAMPLE

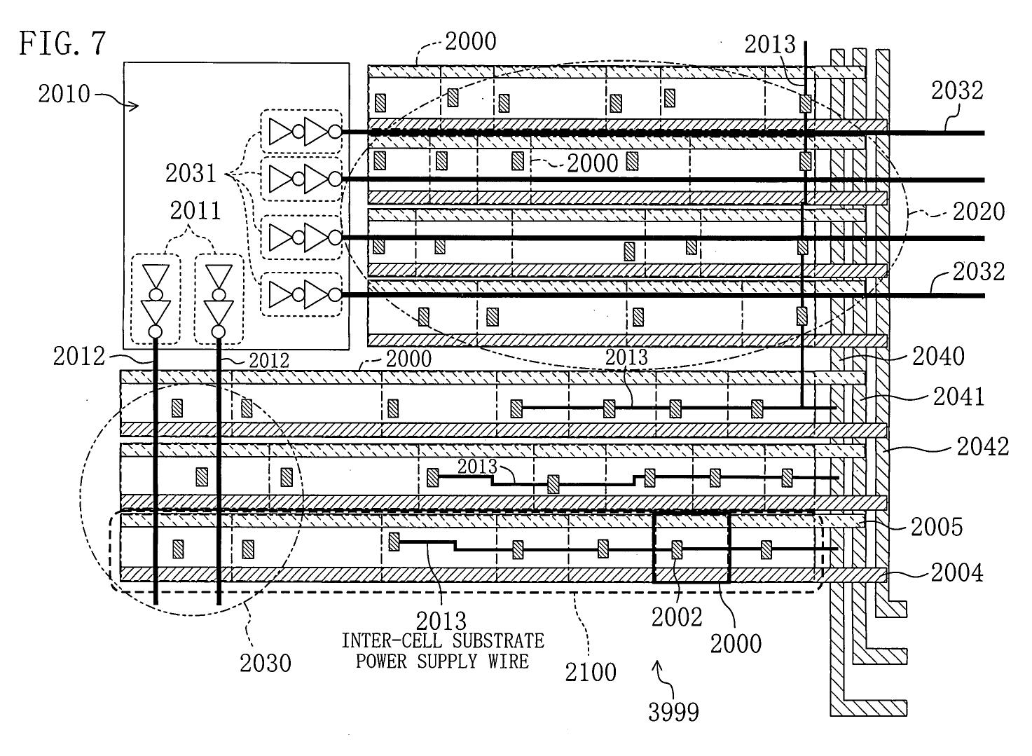

FIG. 7 illustrates a semiconductor integrated circuit according to a third example of the present invention. Note that, in FIG. 7, the same parts as those of FIG. 4 are indicated by the same reference numerals.

The semiconductor integrated circuit 3999 of FIG. 7 is different from the semiconductor integrated circuit of FIG. 4 in that inter-cell substrate power supply wires 2013 connect between substrate power supply terminals 2002 of only a portion of a plurality of standard cells 2000. A p-well region and an n-well region of a standard cell 2000 in the semiconductor integrated circuit 3999 of FIG. 7 are shared by standard cells right and left adjacent thereto, respectively, and the substrate potential is the same among the standard cells 2000.

The semiconductor integrated circuit thus constructed will be hereinafter described.

The inter-cell substrate power supply wire 2013 of the semiconductor integrated circuit 3999 of FIG. 7 is connected to the substrate power supply terminals 2002 of only a portion of the standard cells 2000. However, the well region is shared by left and right adjacent standard cells 2000. Therefore, even when the inter-cell substrate power supply wire 2013 is connected to the substrate power supply terminals 2002 of only a portion of the standard cells as in this example, a substrate potential applied to the inter-cell substrate power supply wire 2013 is supplied to all of the standard cells 2000 in the semiconductor integrated circuit 3999 via the inter-cell substrate power supply wire 2013, the substrate power supply terminal 2002 of the standard cell, and the shared well region.

Thereby, inter-cell substrate power supply wires can be removed from an unnecessary portion, depending on a state of wires surrounding the inter-cell substrate power supply wire 2013 (a state of occurrence of crosstalk noise between the inter-cell substrate power supply wire 2013 and a surrounding wire, the density of wires, etc.), thereby making it possible to reduce crosstalk noise, relax the wire density, and reduce the area.

Although it is illustrated in this example that a single substrate power supply terminal 2002 is provided in each standard cell 2000, a plurality of substrate power supply terminals 2002 may be provided. The inter-cell substrate power supply wire 2013 may be composed only of a metal wire in a single wiring layer, or a metal wire in a plurality of wiring layers. Although there are two inter-cell normal power supply wires 2004 and 2005 in this example, there may be three or more power supply wires 2004 and 2005. Also, although the normal power supply strap wires 2041 and 2042 and the substrate power supply strap wire 2040 are employed in this example, none of them may be used.

### FOURTH EXAMPLE

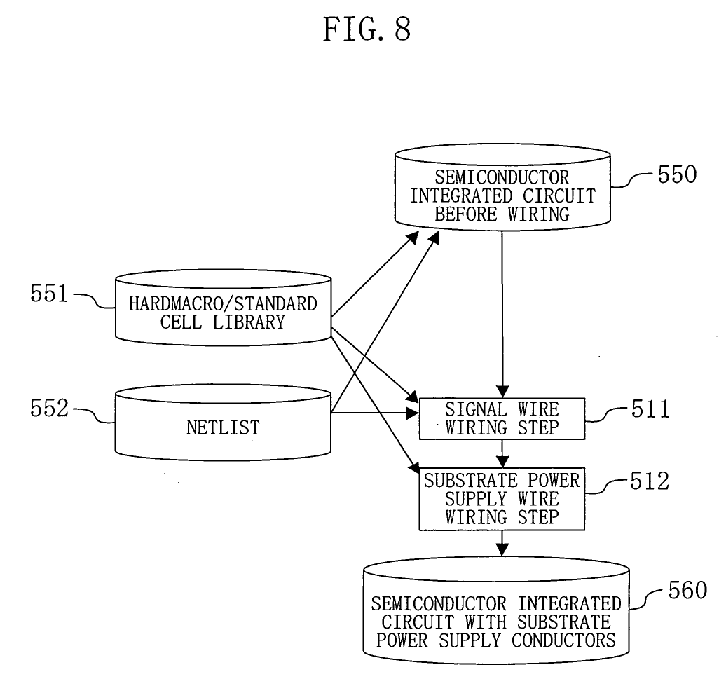

FIG. 8 is a flowchart of a method for designing a layout of a semiconductor integrated circuit.

A hardmacro/standard cell library 551 comprises information about shapes of a hardmacro and a standard cell on mask data, information about physical positions of a signal input terminal and a signal output terminal, information about a speed between the input and output terminals, and power information.

A standard cell included in the hardmacro/standard cell library 551 may be, for example, one as illustrated in FIG. 1A.

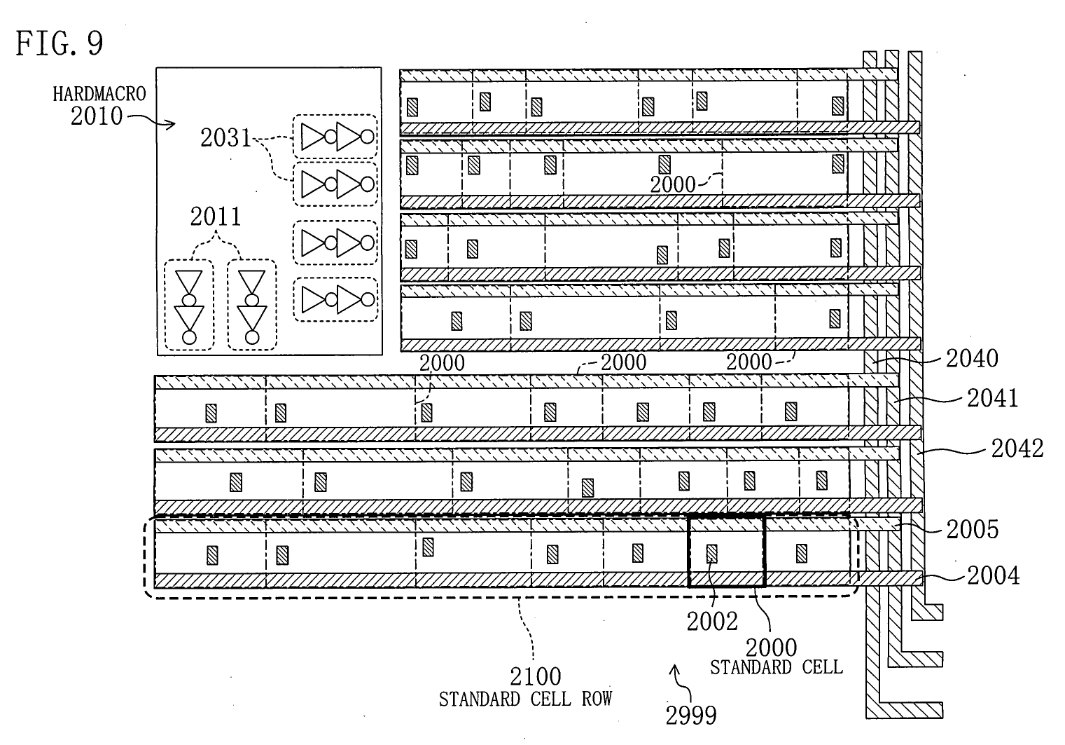

Next, a semiconductor integrated circuit 550 before wiring will be described with reference to the drawings. FIG. 9 is a schematic diagram of a semiconductor integrated circuit 2999 before wiring. In the semiconductor integrated circuit 2999 before wiring, a hardmacro 2010 is disposed in a region in which layout can be performed, based on a file (netlist) of information about connection between logic gates, and standard cells 2000 are disposed along standard cell rows 2100.

The standard cell 2000 is included in the hardmacro/standard cell library 551. The standard cell 2000 arranged in the standard cell row 2100 are laterally adjacent to each other, so that normal power supply wires provided in the standard cells 2000 are connected to each other to form fixed inter-cell wires (inter-cell normal power supply wires) 2004 and 2005. On the other hand, substrate power supply terminals 2002 are not connected to each other in adjacent standard cells 2000.

The hardmacro 2010 comprises output buffers 2011 and 2031. Wiring of signal wires is not yet performed with respect to output terminals of the output buffers 2011 and 2031.

Note that the shape and the number of substrate power supply terminals 2002 are not necessarily the same among the standard cells 2000. Here, for the sake of simplicity, one substrate power supply terminal 2002 is provided for each standard cell 2000.

As a result, the semiconductor integrated circuit 2999 before wiring comprises a plurality of standard cell rows 2100 comprising a plurality of standard cells 2000, the hardmacro 2010 is disposed, and the fixed inter-cell wires 2004 and 2005 are disposed. Note that wiring of signal wires is not performed with respect to the output terminals of the output buffers 2011 and 2031 provided in the hardmacro 2010. Also, the substrate power supply terminals 2002 are not connected to each other.

Hereinafter, a flow of performing wiring with respect to the semiconductor integrated circuit before wiring of FIG. 9 based on the flowchart of the semiconductor integrated circuit designing method of FIG. 8, will be described.

(Step 1)

Signal wires are formed between standard cells and a hardmacro in a signal wire wiring step 511 based on information about connection between logic gates described in a netlist 552, and information about physical positions of both input and output signal terminals (not shown in FIG. 1 or the like) of the hardmacro and the standard cells described in the hardmacro/standard cell library 551. Here, for the sake of simplicity, signal wires between standard cells will not be described.

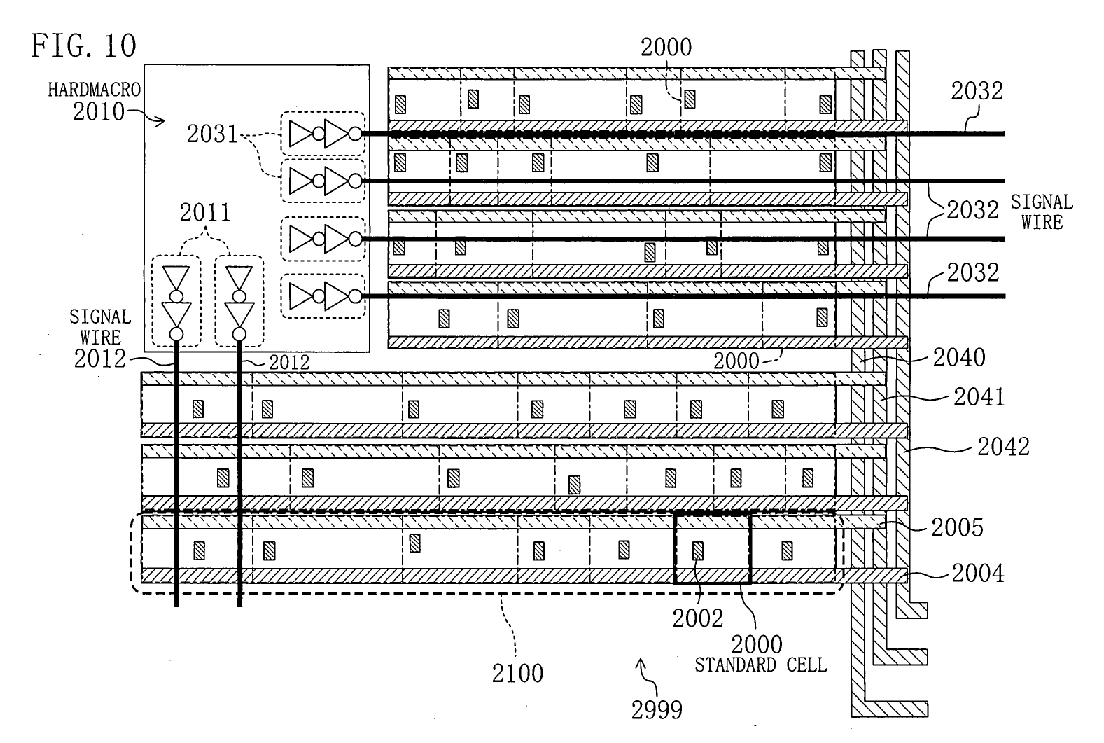

A semiconductor integrated circuit after the signal wire wiring step 511 of step 1 is illustrated in FIG. 10. In FIG. 10, signal wires 2012 and 2032 are formed.

(Step 2)

A wire is formed between substrate power supply terminals 2002 provided in a standard cell 2000 in a substrate power supply wire wiring step 512. In this case, the wiring between the substrate power supply terminals 2002 is performed under the following constraints. A first constraint is that a signal wire driven by a cell having a high level of drive performance and an inter-cell substrate power supply wire between substrate power supply terminals are not disposed adjacent and parallel to each other. When the first constraint is not satisfied, there is a second constraint that a distance along which the signal wire driven by the cell having a high level of drive performance and the inter-cell substrate power supply wire between the substrate power supply terminals, are disposed adjacent and parallel to each other, is minimized.

A semiconductor integrated circuit after the substrate power supply wire wiring step 512 of step 2 is illustrated in FIG. 4. In FIG. 4, the inter-cell substrate power supply wires 2003 are disposed. The inter-cell substrate power supply wire 2003 does not have a portion parallel to the signal wire 2012 or 2032.

As described above, as an output result of the semiconductor integrated circuit designing method of this example, a semiconductor integrated circuit 560 in which substrate power supply wires have been disposed can be obtained.

Thus, in a portion where a signal wire driven by a cell having a high level of drive performance is disposed, a wiring route of an inter-cell substrate power supply wire is determined under the constraint that an inter-cell substrate power supply wire is not disposed parallel to a signal wire. Therefore, it is possible to design a semiconductor integrated circuit which avoids occurrence of crosstalk noise to an inter-cell substrate power supply wire due to parallel wires. Thereby, it is possible to prevent glitch from occurring in an inter-cell substrate power supply wire, suppress a variation in effective threshold voltage of a transistor due to glitch, and suppress a probability of occurrence of an incorrect operation, thereby making it possible to design a semiconductor integrated circuit having an improved yield.

Since the normal power supply wires are composed of the inter-cell normal power supply wires 2004 and 2005 and are previously fixedly provided, so that the normal power supply wires can be electrically connected only by disposing standard cells adjacent to each other, and therefore, the wiring of the normal power supply wires is not additionally required. A wire having a large width or a large wiring interval does not need to be mixed, so that the number of steps required for wiring is not increased. Although the inter-cell substrate power supply wire is not previously fixed in a standard cell in this example, since the wiring width of the inter-cell substrate power supply wire is substantially the same as that of signal wires as described above, the above-described complexity does not occur, and therefore, the number of steps required for wiring is not increased.

Although the step 512 of performing wiring between substrate power supply terminals is performed separately from the signal wire wiring step 511 in this example, both the steps may be simultaneously performed. Also in this case, by performing wiring under the constraint that a wire between substrate power supply terminals and a signal wire are not disposed parallel to each other, an effect similar to that described above can be obtained.

Although it is assumed that a wire is disposed between substrate power supply terminals under the first and second constraints in this example, wiring may be performed under other constraints, such as a constraint that, when a wire between substrate power supply terminals is adjacent to a signal wire driven by a cell having a high level of drive performance, a shield wire is provided between both the wires, thereby making it possible to obtain a similar effect.

### FIFTH EXAMPLE

Next, a semiconductor integrated circuit designing method according to a fifth example of the present invention will be described.

A flow of the design method of this example will be described with reference to FIG. 8 as with the semiconductor integrated circuit designing method of the fourth example.

The flowchart of the semiconductor integrated circuit designing method of this example is different from that of the fourth example in the substrate power supply wire wiring step 512. Hereinafter, the substrate power supply wire wiring step 512 in the semiconductor integrated circuit designing method of the fifth example will be described in detail.

In the substrate power supply wire wiring step 512, wiring between substrate power supply terminals of standard cells is performed in the substrate power supply wire wiring step 512 to form inter-cell substrate power supply wires. In this case, wiring between substrate power supply terminals is performed under the following constraints. A first constraint is that wiring is performed between substrate power supply terminals of all standard cells so that a signal wire driven by a cell having a high level of drive performance and a wire between substrate power supply terminals are not disposed adjacent and parallel to each other. When the first constraint is not satisfied, there is a second constraint that wiring is performed between substrate power supply terminals of a portion of the standard cells so that a signal wire driven by a cell having a high level of drive performance and a wire between substrate power supply terminals are not disposed adjacent and parallel to each other, and a substrate potential is supplied to all of the standard cells. When the second constraint is not satisfied, there is a third constraint that wiring is performed between substrate power supply terminals of all or a portion of the standard cells so that a distance along which a signal wire driven by the cell having a high level of drive performance and a wire between substrate power supply terminals are disposed adjacent and parallel to each other, is minimized.

A result of performing wiring between signal wires and substrate power supply terminals with respect to the semiconductor integrated circuit before wiring of FIG. 9 using the semiconductor integrated circuit designing method of this example, is the semiconductor integrated circuit of FIG. 7. Note that FIG. 7 is similar to the semiconductor integrated circuit of the third example and will not be described in detail.

As described above, the semiconductor integrated circuit 560 in which substrate power supply wires have been disposed can be obtained as an output result of the semiconductor integrated circuit designing method of this example.

As described above, according to the flow of the semiconductor integrated circuit designing method of this example, in addition to the effect of the semiconductor integrated circuit designing method of the fourth example, inter-cell substrate power supply wires can be removed from an unnecessary portion, depending on states of inter-cell substrate power supply wires and surrounding wires, thereby making it possible to further reduce crosstalk noise.

Although the step 512 of performing wiring between substrate power supply terminals is performed separately from the signal wire wiring step 511 in this example, both the steps may be simultaneously performed. Also in this case, by performing wiring under the constraint that a wire between substrate power supply terminals and a signal wire are not disposed parallel to each other, an effect similar to that described above can be obtained.

Although it is assumed that a wire is disposed between substrate power supply terminals under the first, second and third constraints in this example, wiring may be performed under other constraints, such as a constraint that, when a wire between substrate power supply terminals is adjacent and parallel to a signal wire driven by a cell having a high level of drive performance, a shield wire is provided between both the wires, a constraint that wiring between substrate power supply terminals is not performed in a portion having a high wire density, or the like. In this case, in addition to a similar effect, the wire density can relaxed and the area can be reduced.

### SIXTH EXAMPLE

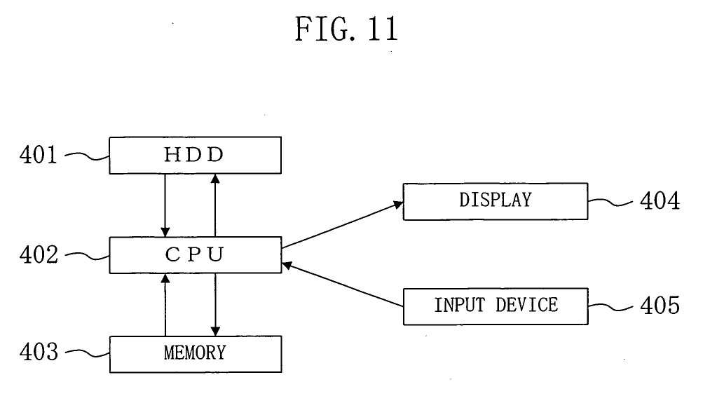

FIG. 11 illustrates a semiconductor integrated circuit designing apparatus according to a sixth example of the present invention.

In FIG. 11, the semiconductor integrated circuit designing apparatus comprises: a CPU 402 which has a signal wire wiring circuit and a substrate power supply wire wiring circuit (both not shown) for executing the signal wire wiring step 511 and the substrate power supply wire wiring step 512 of FIG. 8, respectively, and performs a computation process, such as wiring or the like; a hard disk drive (HDD) 401 for storing a library, a netlist, a design condition file, and a program for processing them; a memory 403 for temporarily storing data stored in the HDD 401 and a result of a computation process by the CPU 402; an input device 405 which is composed of a mouse and a keyboard and is used by a designer to give a command to the CPU 402; and a display 404 for, for example, displaying a result of a process performed by the CPU 402.

The designer inputs a command or the like about arrangement and wiring and LSI design via the input device 405 to the CPU 402. In accordance with the command, the CPU 402 performs a predetermined process based on data stored and saved in the HDD 401 and the memory 403, stores the process result into the HDD 401 and the memory 403, and displays the process result on the display 404.

By using the semiconductor integrated circuit designing apparatus thus constructed, the designer can design a semiconductor integrated circuit.

What is claimed is:

1. A standard cell comprising:
a normal power supply wire for supplying a power supply voltage to sources of transistors; and
a substrate power supply wire for supplying a substrate power supply voltage to a substrate of the transistors,
wherein the normal power supply wire is composed of a fixed wire whose position in a height direction and wiring width are set to be the same as those of another standard cell of a kind different from that of the standard cell, and which is disposed across the standard cell in a direction perpendicular to the height direction, and
the substrate power supply wire is composed of a non-fixed wire different from the fixed wire.

2. The standard cell of claim 1, wherein, when the standard cell is disposed adjacent to another standard cell, the non-fixed wire is not connected to a non-fixed wire of the other standard cell.

3. The standard cell of claim 1, wherein the non-fixed wire is provided in each of an n-well region and a p-well region.

4. The standard cell of claim 1, wherein a plurality of the non-fixed wires are provided.

5. The standard cell of claim 1, wherein the non-fixed wire is a substrate power supply terminal for supplying the substrate power supply voltage.

6. The standard cell of claim 5, wherein the substrate power supply terminal is provided in each of an n-well region and a p-well region.

7. The standard cell of claim 5, wherein a plurality of the substrate power supply terminals are provided.

8. A standard cell library comprising the standard cell of claim 1.

9. A semiconductor integrated circuit comprising the standard cell of claim 1.

10. A semiconductor integrated circuit composed of a plurality of standard cell rows including a plurality of standard cells, comprising:
a normal power supply wire network for supplying a power supply voltage to sources of transistors included in each standard cell; and
a substrate power supply wire network for supplying a substrate power supply voltage of a substrate of the transistors of each standard cell,
wherein the normal power supply wire network includes a fixed inter-cell wire disposed in a width direction along each standard cell row, and
the substrate power supply wire network includes a non-fixed inter-cell wire different from the fixed inter-cell wire.

11. The semiconductor integrated circuit of claim 10, wherein the non-fixed inter-cell wire is composed of a plurality of wires for supplying the substrate power supply voltage to each of an n-well region and a p-well region of each standard cell.

12. The semiconductor integrated circuit of claim 10, wherein the non-fixed inter-cell wire is configured by connecting substrate power supply terminals provided in the standard cells.

13. The semiconductor integrated circuit of claim 10, wherein the non-fixed inter-cell wire is configured by connecting a portion of substrate power supply terminals provided in the standard cells.

14. The semiconductor integrated circuit of claim 10, wherein the normal power supply wire network comprises a normal power supply strap wire which is disposed in a direction perpendicular to the fixed inter-cell wire and is connected to the fixed inter-cell wire.

15. The semiconductor integrated circuit of claim 14, wherein the substrate power supply wire network comprises a substrate power supply strap wire which is disposed parallel to the normal power supply strap wire and is connected to the non-fixed inter-cell wire.

16. The semiconductor integrated circuit of claim 15, wherein the substrate power supply strap wire has, a wiring width larger than that of the non-fixed inter-cell wire.

17. A semiconductor integrated circuit including a number of transistors, comprising:
a normal power supply wire network for supplying a power supply voltage to a source of each transistor;
a substrate power supply wire network for supplying a substrate power supply voltage to a substrate of each transistor; and
a plurality of signal wires,
wherein the normal power supply wire network is disposed, extending in a predetermined wiring layer in a single direction, and
the substrate power supply wire network is disposed in a plurality of wiring layers in a plurality of directions so as to circumvent the normal power supply wire network and the plurality of signal wires.
